(19) United States
(12) Patent Application Publication
(10) Pub. No.: US 2014/0318628 A1
(43) Pub. Date: Oct. 30, 2014

(54) Conjugated Polymers Containing Fused Electron Rich and Electron Poor Units, Preparation, Method and Uses

(71) Applicant: Advent Technologies Inc., East Hartford, CT (US)

(72) Inventors: Christos L. Chochos, Athens (GR); Vasilis G. Gregoriou, East Hartford, CT (US)

(73) Assignee: ADVENT TECHNOLOGIES INC., East Hartford, CT (US)

(21) Appl. No.: 14/266,094

(22) Filed: Apr. 30, 2014

Related U.S. Application Data
(60) Provisional application No. 61/817,386, filed on Apr. 30, 2013.

(51) Int. Cl. H01L 51/00; H01L 31/18; C08G 75/06

(52) U.S. Cl. CPC H01L 51/0036; C08G 75/06; H01L 31/18
USPC 136/263; 528/210; 427/58

(57) ABSTRACT

New conjugated polymers based on 2,3-diphenylquinoxaline, dibenzo[a,c]phenazine, 2,3-diphenylpyrido[3,4-b]pyrazine, dibenzo[f,h]pyrido[3,4-b]quinoxaline, 2,3-diphenylpyrazino[2,3-d]pyridazine and dibenzo[f,h]pyridazino[4,5-b]quinoxaline along with their derivatives and thiophene, thieno[3,2-b]thiophene and thieno[2,3-b]thiophene along with their derivatives and a preparation method and uses thereof are disclosed.

### CROSS REFERENCE TO RELATED APPLICATION

This patent application claims a benefit to the filing date of U.S. Provisional Patent Application Ser. No. 61/817,386 titled, “Conjugated Polymers Containing Fused Electron Rich and Electron Poor Units, Preparation Method and Uses Thereof,” that was filed on Apr. 30, 2013. The disclosure of U.S. 61/817,386 is incorporated by reference herein in its entirety.

### FIELD OF INVENTION

The present invention relates to the technical field of synthesis of conjugated polymers, particularly to alternating copolymers containing thiophene, thieno[3,2-b]thiophene or thieno[2,3-b]thiophene moieties as electron rich compounds with various electron withdrawing building blocks such as 2,3-diphenylquinoxaline, dibenzo[a,c]phenazine, 2,3-diphenylpyrido[3,4-b]pyrazine, dibenzo[f,h]pyrido[3,4-b]quinoxaline, 2,3-diphenylpyrazino[2,3-d]pyridazine and dibenzo[f,h]pyridazino[4,5-b]quinoxaline, and preparation method and uses thereof.

### BACKGROUND INFORMATION

Organic and polymer photovoltaic cells are an extremely active area of research, in order to meet the urgent need for clean and renewable sources of energy. During the last decade the field of polymer photovoltaics has shown a continuous improvement in both device efficiency and understanding of the underlying physical processes. Despite exhibiting lower power conversion efficiency (PCE) in comparison to conventional inorganic technologies, polymer photovoltaic cells have attracted particular attention due to their potential applications as flexible, low-cost and solution processible energy sources. At present the so-called bulk heterojunction (BHJ) structure based on blends of conjugated polymers as electron donors and soluble fullerene derivatives (especially [6,6]-phenyl-C61-butyric acid methyl ester (PC₆₁BM) or [6,6]-phenyl-C71-butyric acid methyl ester (PC₇₁BM)) as electron acceptors represent one of the most extensively studied type of organic photovoltaics (OPVs) with PCEs in the range of 6-8% (Chochos and Choulis 2011). On the OPV technology roadmap towards higher PCEs, studies on existing materials have identified parameters limiting the PCE in organic BHJ solar cells. These include the charge mobility, the optical band gap (E_{g}), the ionization potential (HOMO level) and electron affinity (LUMO level) from the part of the conjugated polymer, the elimination of rotational barriers and the recently reported charge transfer (CT) state of both components. Hence, in order to further enhance the PCE and to obtain the desired performances with polymeric semiconductors, different parameters at the molecular and supramolecular levels (such as electronic structure, regioregularity, purity, solubility, molecular weight, thermal transitions, crystallinity and morphology within the blend) should be carefully controlled. For example, the good solubility of polymers in common organic solvents is an essential parameter for the utilization of low-cost solution processing techniques. The polymer solubility as well as the miscibility with fullerene derivatives is usually controlled by the choice of the side chain, its structure (linear or branched), and its position along the backbone. However, it is not easy to predict how such structural modifications at the molecular level affect many of the above-mentioned parameters.

At present it is possible to calculate the theoretical PCE of a BHJ solar cell consisting of an electron D polymer blended with PCBM based on the E_{g} of the D along with the difference between the LUMO level of the D with the LUMO level of the A and experimental predicted values for the device external quantum efficiency (EQE) and fill factor (FF). Therefore, conjugated polymer control over the HOMO-LUMO energy gap it is one of the most important parameters for high PCE and has been extensive studied from the view of synthetic chemistry. The tuning and modification of the band gap of a conjugated polymer is a multiparameter effect involving six factors: molecular weight, bond, length alternation (E_{BLA}), planarity (E_{θ}), aromatic resonance energy (E_{Res}), substituents (E_{sub}) and intermolecular interactions (Eᵢₙₜₑᵣ), thus, the design and synthesis of most of the low band gap (LBG) polymers reported in literature, is rationally based on these parameters. However the exact control of individually the HOMO and LUMO energy levels is not a very simple process because despite the fact that all the above mentioned six parameters have an influence on the band gap, they also related to each other, affecting other important chemical, mechanical, and physical properties. For example, even though the solubility of conjugated polymers is increased by the use of large alkyl or alkoxy chains, this is also influences the E_{sub}, the tendency for supramolecular arrangement Eᵢₙₜₑᵣ and finally the increment of the torsion angle (E_{θ}). Therefore, any external stimulus that will modify the planarity of the backbone and the degree of π-orbital overlap, will alter E_{g} and as a sequence the relative position of the HOMO and LUMO levels. Thus, by synthesizing LBG conjugated polymers for solar cells the positioning as well as the nature of the substituents must be carefully designed and selected properly. When substituents are employed, it is important to arrange them in a regioregular way to avoid steric effects that would cause twisting of the main chain. Another way to insure greater conjugation is to rigidify the individual monomer units by employing additional rings that serve to enforce planarity and this also minimizes or eliminates steric crowding.

In order to achieve practical applications of the polymeric solar cells, the most important task in this research field is to develop new materials and to significantly increase its energy transfer efficiency.

### SUMMARY OF THE INVENTION

New conjugated polymers based on 2,3-diphenylquinoxaline, dibenzo[a,c]phenazine, 2,3-diphenylpyrido[3,4-b]pyrazine, dibenzo[f,h]pyrido[3,4-b]quinoxaline, 2,3-diphenylpyrazino[2,3-d]pyridazine and dibenzo[f,h]pyridazino[4,5-b]quinoxaline along with their derivatives as electron withdrawing units and thiophene, thieno[3,2-b]thiophene and thieno[2,3-b]thiophene along with their derivatives as electron rich compounds and a preparation method and uses thereof are disclosed. The polymers may be used in the fields of polymer solar cell and field effect transistors and the like due to good solubility, high carrier mobility and relatively strong modifiability of chemical property and chemical structure. The preparation method is simple and can be handled and controlled easily.

### BRIEF DESCRIPTION OF THE DRAWINGS

FIG. 1 illustrates an optoelectronic device for use with the conjugated structures disclosed herein.

FIG. 2 illustrates a field-effect transistor (FET) for use with the conjugated structures disclosed herein.

### DETAILED DESCRIPTION OF THE INVENTION

The present invention relates to the development of new conjugated polymers (structures 1-54) comprising alternating copolymers bearing thiophene, thieno[3,2-b]thiophene or thieno[2,3-b]thiophene moieties and new electron withdrawing building blocks such as 2,3-diphenylquinoxaline, dibenzo[a,c]phenazine, 2,3-diphenylpyrido[3,4-b]pyrazine, dibenzo[f,h]pyrido[3,4-b]quinoxaline, 2,3-diphenylpyrazino[2,3-d]pyridazine and dibenzo[f,h]pyridazino[4,5-b]quinoxaline. The structures of the materials are given below.

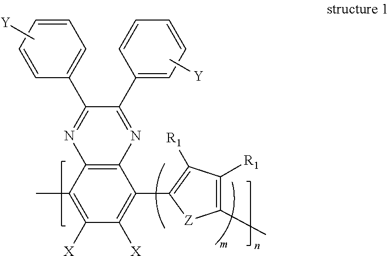

wherein X, Y, Z can be the same or different and is selected from the group consisting of: X=hydrogen or fluorine atoms;
Y=alkyl, alkoxy; in ortho, meta or para positions and can be linear or branch;
Z=oxygen, sulfur, selenium;
m and n can be the same or different and are numbers between 1 to 1000
and R₁: —CₚH₂ₚ₊₁, p≧0; linear or branch.

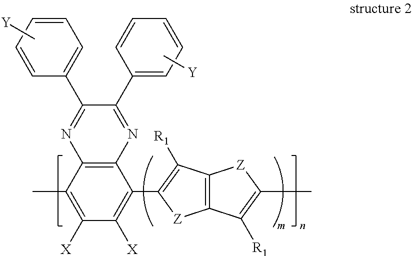

wherein X, Y, Z can be the same or different and is selected from the group consisting of: X=hydrogen or fluorine atoms;
Y=alkyl, alkoxy; in ortho, meta or para positions and can be linear or branch;
Z=oxygen, sulfur, selenium;
m and n can be the same or different and are numbers between 1 to 1000
and R₁: —CₚH₂ₚ₊₁, p≧0; linear or branch.

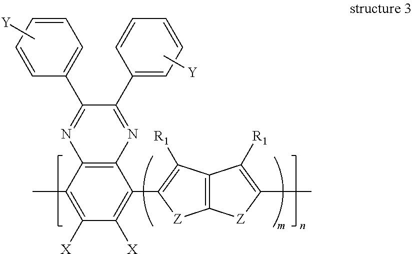

wherein X, Y, Z can be the same or different and is selected from the group consisting of: X=hydrogen or fluorine atoms;
Y=alkyl, alkoxy; in ortho, meta or para positions and can be linear or branch;
Z=oxygen, sulfur, selenium;
m and n can be the same or different and are numbers between 1 to 1000
and R₁: —CₚH₂ₚ₊₁, p≧0; linear or branch.

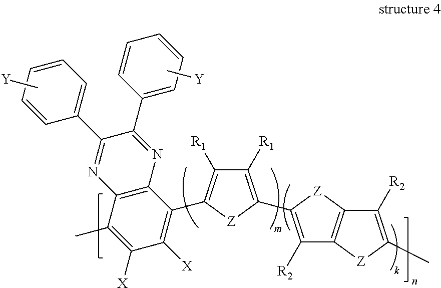

wherein X, Y, Z can be the same or different and is selected from the group consisting of: X=hydrogen or fluorine atoms;
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}H_{2w+1}, w≧0; linear or branch.

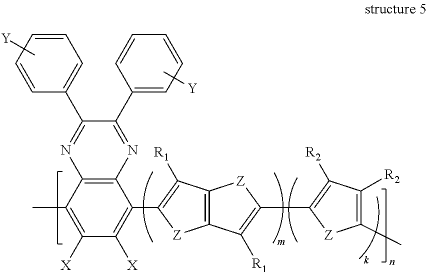

wherein X, Y, Z can be the same or different and is selected from the group consisting of: X=hydrogen or fluorine atoms;
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}H_{2w+1}, W≧0; linear or branch.

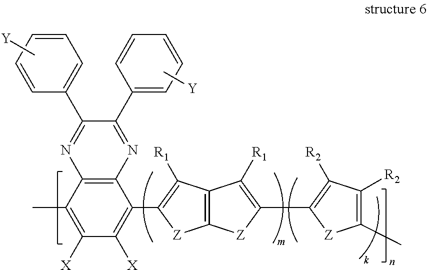

wherein X, Y, Z can be the same or different and is selected from the group consisting of: X=hydrogen or fluorine atoms;
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}H_{2w+1}, w≧0; linear or branch.

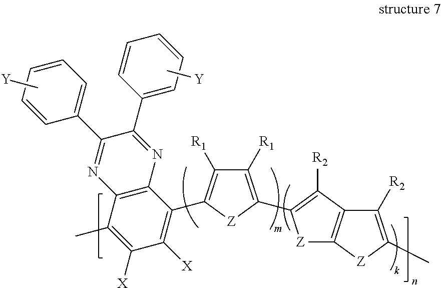

wherein X, Y, Z can be the same or different and is selected from the group consisting of: X=hydrogen or fluorine atoms;
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}H_{2w+1}, w≧0; linear or branch.

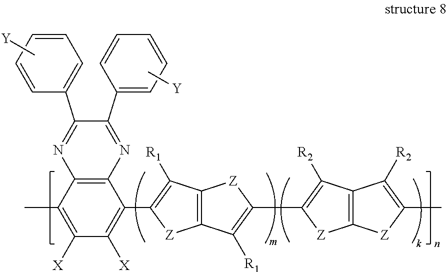

wherein X, Y, Z can be the same or different and is selected from the group consisting of: X=hydrogen or fluorine atoms;
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}H_{2w+1}, w≧0; linear or branch.

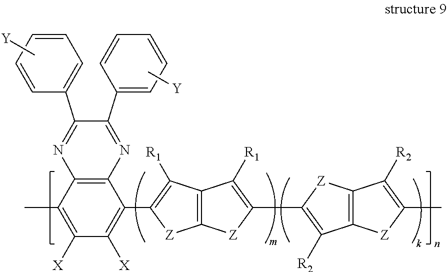

wherein X, Y, Z can be the same or different and is selected from the group consisting of: X=hydrogen or fluorine atoms;
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}H_{2w+1}, w≧0; linear or branch.

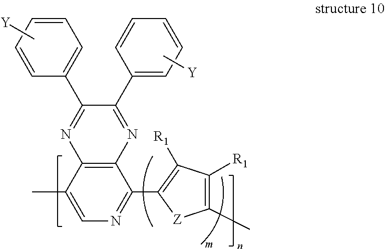

wherein Y, Z can be the same or different and is selected from the group consisting of:
Y=alkyl, alkoxy; in ortho, meta or para positions and can be linear or branch;
Z=oxygen, sulfur, selenium;
m and n can be the same or different and are numbers between 1 to 1000
and R₁: —CₚH₂ₚ₊₁, p≧0; linear or branch.

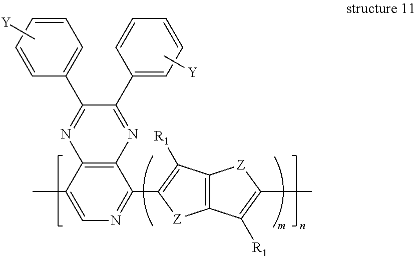

wherein Y, Z can be the same or different and is selected from the group consisting of:
Y=alkyl, alkoxy; in ortho, meta or para positions and can be linear or branch;
Z=oxygen, sulfur, selenium;
m and n can be the same or different and are numbers between 1 to 1000
and R₁: —CₚH₂ₚ₊₁, p≧0; linear or branch.

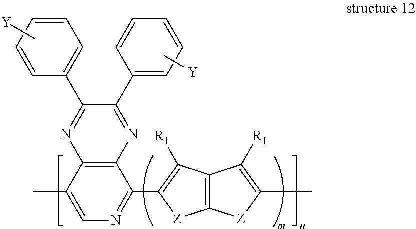

wherein Y, Z can be the same or different and is selected from the group consisting of:
Y=alkyl, alkoxy; in ortho, meta or para positions and can be linear or branch;
Z=oxygen, sulfur, selenium;
m and n can be the same or different and are numbers between 1 to 1000
and R₁: —CₚH₂ₚ₊₁, p≧0; linear or branch.

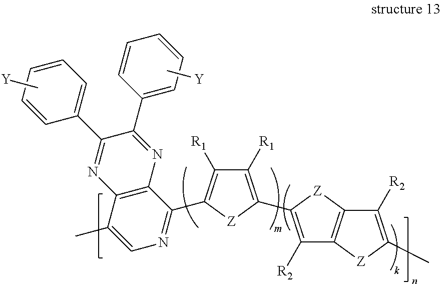

wherein Y, Z can be the same or different and is selected from the group consisting of:
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}H_{2w+1}, w≧0; linear or branch.

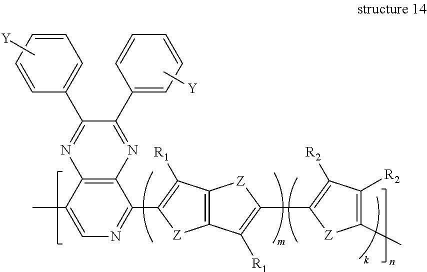

wherein Y, Z can be the same or different and is selected from the group consisting of:
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}H_{2w+1}, w≧0; linear or branch.

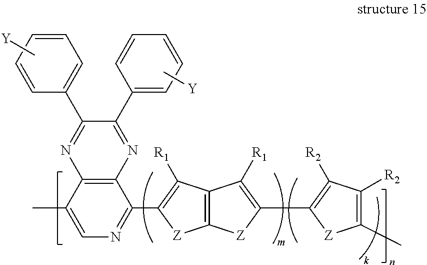

wherein Y, Z can be the same or different and is selected from the group consisting of:
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}H_{2w+1}, w≧0; linear or branch.

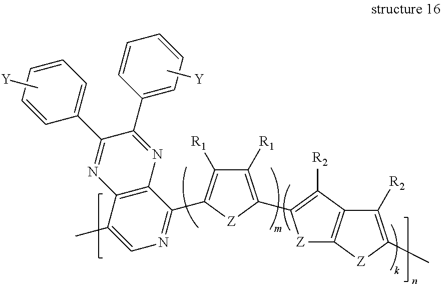

wherein Y, Z can be the same or different and is selected from the group consisting of:
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}H_{2w+1}, w≧0; linear or branch.

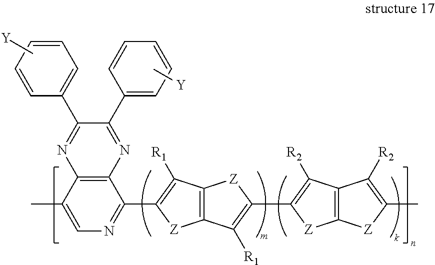

wherein Y, Z can be the same or different and is selected from the group consisting of:
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}H_{2w+1}, w≧0; linear or branch.

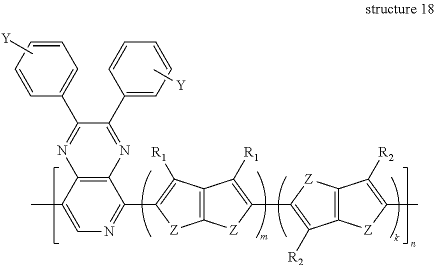

wherein Y, Z can be the same or different and is selected from the group consisting of:
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}H_{2w+1}, w≧0; linear or branch.

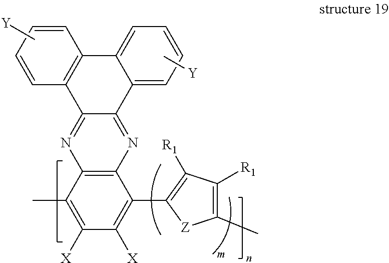

wherein X, Y, Z can be the same or different and is selected from the group consisting of: X=hydrogen or fluorine atoms;
Y=alkyl, alkoxy; in ortho, meta or para positions and can be linear or branch;
Z=oxygen, sulfur, selenium;
m and n can be the same or different and are numbers between 1 to 1000
and R₁: —CₚH₂ₚ₊₁, p≧0; linear or branch.

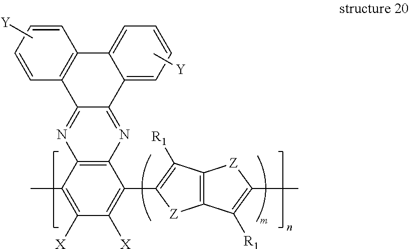

wherein X, Y, Z can be the same or different and is selected from the group consisting of: X=hydrogen or fluorine atoms;
Y=alkyl, alkoxy; in ortho, meta or para positions and can be linear or branch;
Z=oxygen, sulfur, selenium;
m and n can be the same or different and are numbers between 1 to 1000
and R₁: —CₚH₂ₚ₊₁, p≧0; linear or branch.

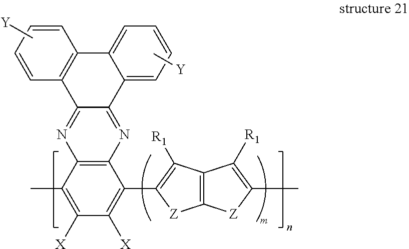

wherein X, Y, Z can be the same or different and is selected from the group consisting of: X=hydrogen or fluorine atoms;
Y=alkyl, alkoxy; in ortho, meta or para positions and can be linear or branch;
Z=oxygen, sulfur, selenium;
m and n can be the same or different and are numbers between 1 to 1000
and R₁: —CₚH₂ₚ₊₁, p≧0; linear or branch.

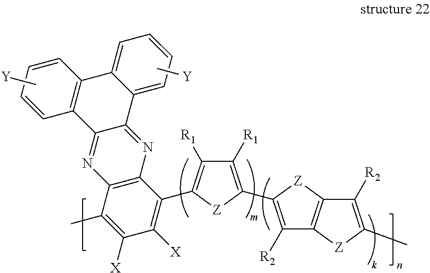

wherein X, Y, Z can be the same or different and is selected from the group consisting of: X=hydrogen or fluorine atoms;
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}H_{2w+1}, w≧0; linear or branch.

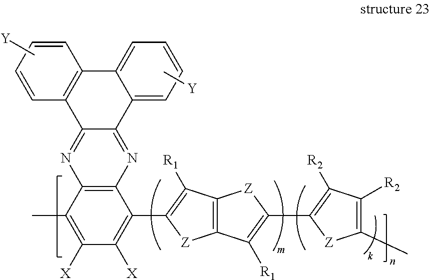

wherein X, Y, Z can be the same or different and is selected from the group consisting of: X=hydrogen or fluorine atoms;
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}H_{2w+1}, w≧0; linear or branch.

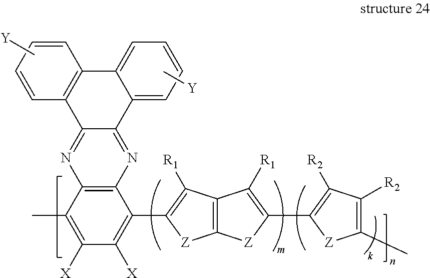

wherein X, Y, Z can be the same or different and is selected from the group consisting of: X=hydrogen or fluorine atoms;
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}H_{2w+1}, w≧0; linear or branch.

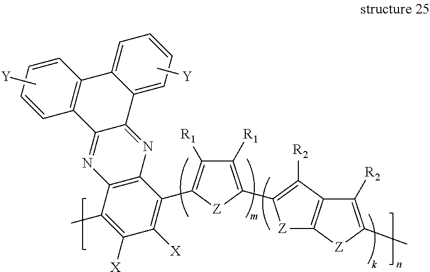

wherein X, Y, Z can be the same or different and is selected from the group consisting of: X=hydrogen or fluorine atoms;
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}H_{2w+1}, w≧0; linear or branch.

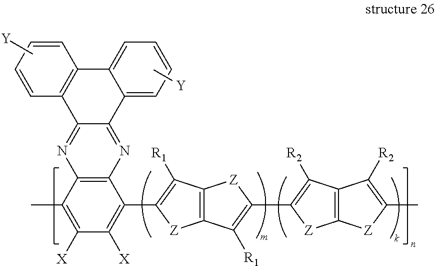

wherein X, Y, Z can be the same or different and is selected from the group consisting of: X=hydrogen or fluorine atoms;
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}H_{2w+1}, w≧0; linear or branch.

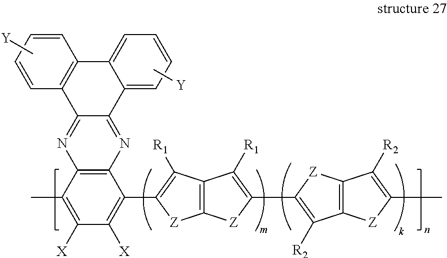

wherein X, Y, Z can be the same or different and is selected from the group consisting of: X=hydrogen or fluorine atoms;
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}H_{2w+1}, w≧0; linear or branch.

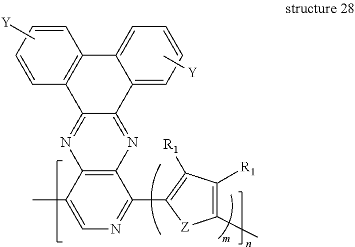

wherein Y, Z can be the same or different and is selected from the group consisting of:
Y=alkyl, alkoxy; in ortho, meta or para positions and can be linear or branch;
Z=oxygen, sulfur, selenium;
m and n can be the same or different and are numbers between 1 to 1000
and R₁: —CₚH₂ₚ₊₁, p≧0; linear or branch.

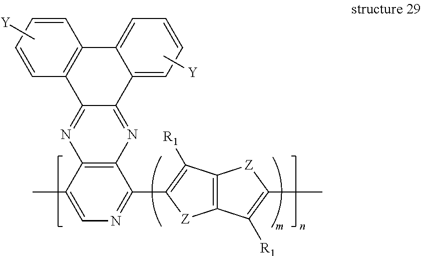

wherein Y, Z can be the same or different and is selected from the group consisting of:
Y=alkyl, alkoxy; in ortho, meta or para positions and can be linear or branch;
Z=oxygen, sulfur, selenium;
m and n can be the same or different and are numbers between 1 to 1000
and R₁: —CₚH₂ₚ₊₁, p≧0; linear or branch.

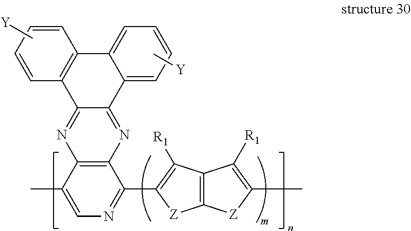

wherein Y, Z can be the same or different and is selected from the group consisting of:
Y=alkyl, alkoxy; in ortho, meta or para positions and can be linear or branch;
Z=oxygen, sulfur, selenium; m and n can be the same or different and are numbers between 1 to 1000
and R₁: —CₚH₂ₚ₊₁, p≧0; linear or branch.

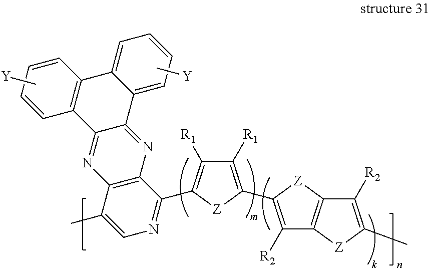

wherein Y, Z can be the same or different and is selected from the group consisting of:
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}H_{2w+1}, w≧0; linear or branch.

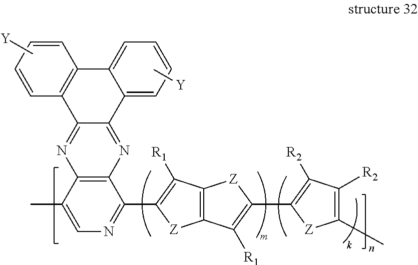

wherein Y, Z can be the same or different and is selected from the group consisting of:
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}H_{2w+1}, w≧0; linear or branch.

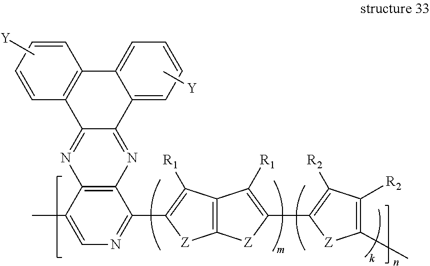

wherein Y, Z can be the same or different and is selected from the group consisting of:
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}H_{2w+1}, w≧0; linear or branch.

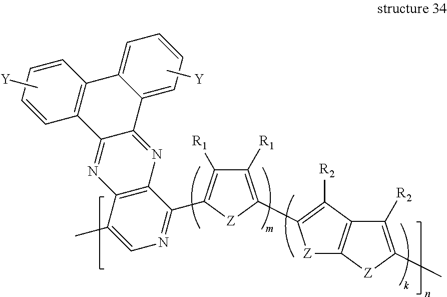

wherein Y, Z can be the same or different and is selected from the group consisting of:
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p 0; linear or branch
and R₂: —C_{w}H_{2w+1}, w≧0; linear or branch.

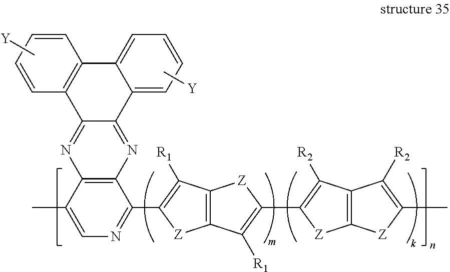

wherein Y, Z can be the same or different and is selected from the group consisting of:
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}H_{2w+1}, w≧0; linear or branch.

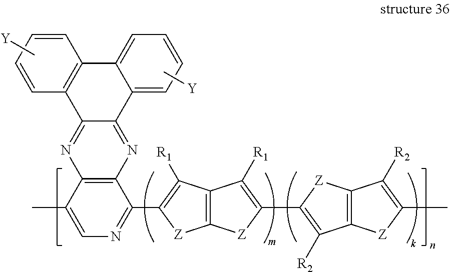

wherein Y, Z can be the same or different and is selected from the group consisting of:
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}H_{2w+1}, w≧0; linear or branch.

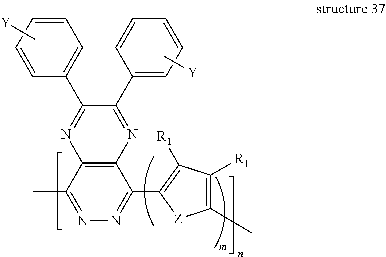

wherein Y, Z can be the same or different and is selected from the group consisting of:
Y=alkyl, alkoxy; in ortho, meta or para positions and can be linear or branch;
Z=oxygen, sulfur, selenium; m and n can be the same or different and are numbers between 1 to 1000
and R₁: —CₚH₂ₚ₊₁, p≧0; linear or branch.

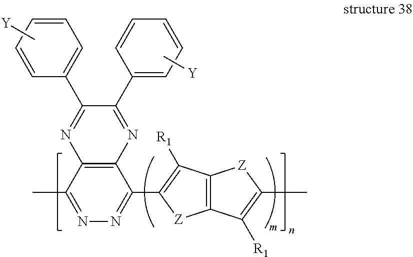

wherein Y, Z can be the same or different and is selected from the group consisting of:
Y=alkyl, alkoxy; in ortho, meta or para positions and can be linear or branch;
Z=oxygen, sulfur, selenium; m and n can be the same or different and are numbers between 1 to 1000
and R₁: —CₚH₂ₚ₊₁, p≧0; linear or branch.

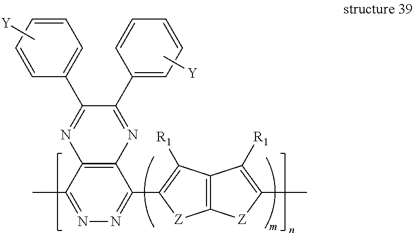

wherein Y, Z can be the same or different and is selected from the group consisting of:
Y=alkyl, alkoxy; in ortho, meta or para positions and can be linear or branch;
Z=oxygen, sulfur, selenium; m and n can be the same or different and are numbers between 1 to 1000
and R₁: —CₚH₂ₚ₊₁, p≧0; linear or branch.

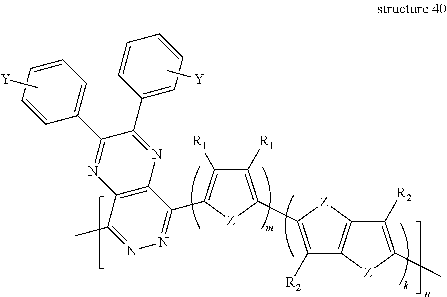

wherein Y, Z can be the same or different and is selected from the group consisting of:
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}H_{2w+1}, w≧0; linear or branch.

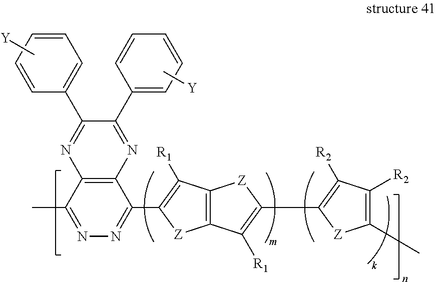

wherein Y, Z can be the same or different and is selected from the group consisting of:
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}H_{2w+1}, w≧0; linear or branch

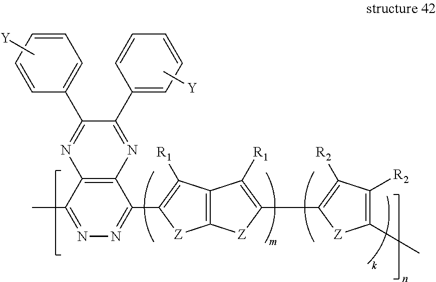

wherein Y, Z can be the same or different and is selected from the group consisting of:
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}H_{2w+1}, w≧0; linear or branch.

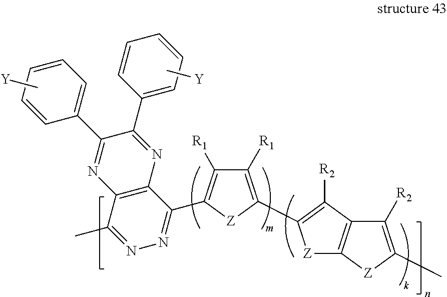

wherein Y, Z can be the same or different and is selected from the group consisting of:
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}H_{2w+1}, w≧0; linear or branch.

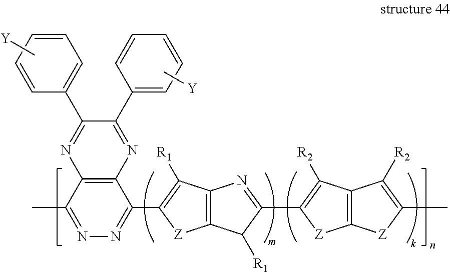

wherein Y, Z can be the same or different and is selected from the group consisting of:
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}H_{2w+1}, w≧0; linear or branch.

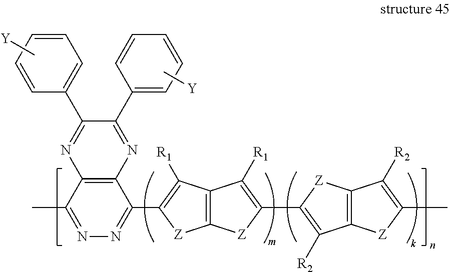

wherein Y, Z can be the same or different and is selected from the group consisting of:
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}H_{2w+1}, w≧0; linear or branch.

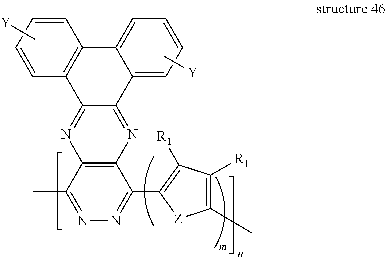

wherein Y, Z can be the same or different and is selected from the group consisting of:
Y=alkyl, alkoxy; in ortho, meta or para positions and can be linear or branch;
Z=oxygen, sulfur, selenium; m and n can be the same or different and are numbers between 1 to 1000
and R₁: —CₚH₂ₚ₊₁, p≧0; linear or branch.

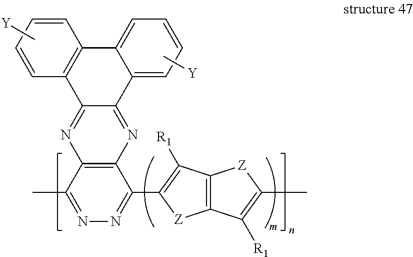

wherein Y, Z can be the same or different and is selected from the group consisting of:
Y=alkyl, alkoxy; in ortho, meta or para positions and can be linear or branch;
Z=oxygen, sulfur, selenium;
m and n can be the same or different and are numbers between 1 to 1000
and R₁: —CₚH₂ₚ₊₁, p≧0; linear or branch.

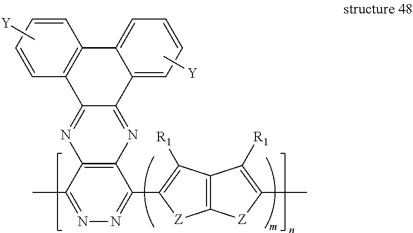

wherein Y, Z can be the same or different and is selected from the group consisting of:
Y=alkyl, alkoxy; in ortho, meta or para positions and can be linear or branch;
Z=oxygen, sulfur, selenium; m and n can be the same or different and are numbers between 1 to 1000
and R₁: —CₚH₂ₚ₊₁, p≧0; linear or branch.

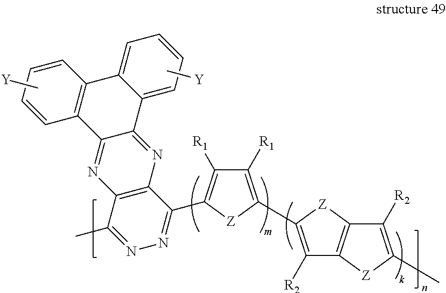

wherein Y, Z can be the same or different and is selected from the group consisting of:
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}H_{2w+1}, w≧0; linear or branch.

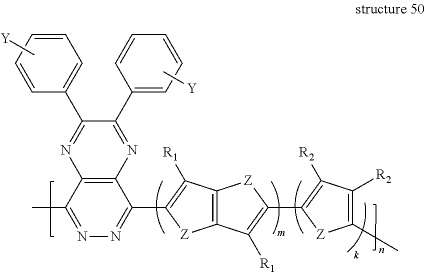

wherein Y, Z can be the same or different and is selected from the group consisting of:
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}H_{2w+1}, w≧0; linear or branch.

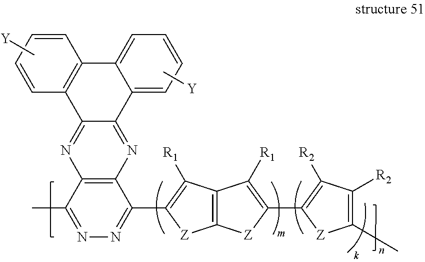

wherein Y, Z can be the same or different and is selected from the group consisting of:
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}H_{2w+1}, w≧0; linear or branch.

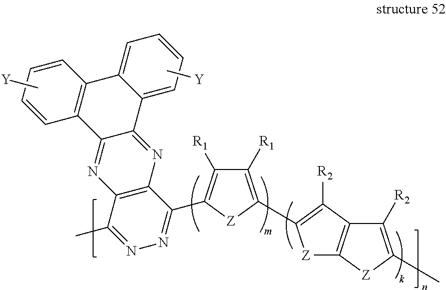

wherein Y, Z can be the same or different and is selected from the group consisting of:
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}H_{2w+1}, w≧0; linear or branch.

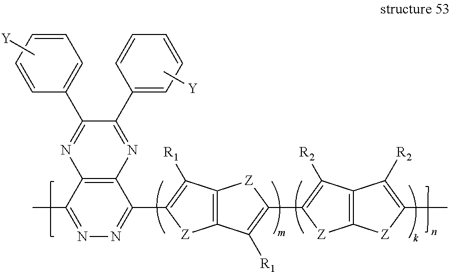

wherein Y, Z can be the same or different and is selected from the group consisting of:
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}H_{2w+1}, w≧0; linear or branch.

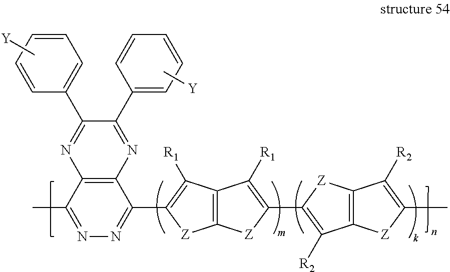

wherein Y, Z can be the same or different and is selected from the group consisting of:
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}H_{2w+1}, w≧0; linear or branch.

### EXAMPLES

The following non-limiting examples are illustrative of the invention. All documents mentioned herein are incorporated herein by reference.

### Example 1

### Synthesis of 5,8-dibromo-2,3-bis(3-(octyloxy)phenyl)quinoxaline

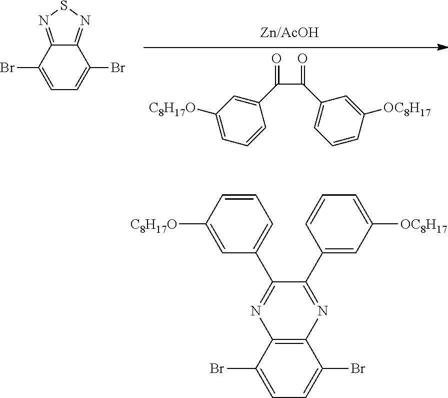

To a suspension of zinc (5 g, 77 mmol) and 4,7-dibromobenzo[c][1,2,5]thiadiazole (4.41 g, 15 mmol) in acetic acid (100 mL), a few drops of water was added. The mixture was stirred at 60° C. for 6 h. After that, the solid residue was removed by filtration. And then 1,2-bis(3-(octyloxy)phenyl)ethane-1,2-dione (6 g, 12.9 mmol) was added to the filtrate. The resulting solution was stirred at 60° C. overnight. The mixture was transferred to a separatory funnel, extracted with diethyl ether and then washed with water. The ether phase was dried over MgSO₄. The crude product was purified by silica-gel column chromatography with a mixture of hexane:dichloromethane=1:1 as eluent to obtain the pure product as a yellow solid (7.91 g, 88%). ¹H NMR (500 MHz, CDCl₃, δ): 7.92 (s, 2H), 7.24 (m, 4H), 7.19 (d, J=6.6 Hz, 2H), 6.93 (d, J=7.8 Hz, 2H), 3.86 (t, 4H; OCH₂), 1.73 (m, 4H; CH₂), 1.30-1.43 (m, 20H; CH₂), 0.89 (t, 6H; CH₃); ¹³C NMR (125 MHz, CDCl₃, δ): 159.0, 154.0, 139.3, 139.1, 133.1, 129.3, 123.7, 122.5, 116.5, 115.7, 68.1, 31.8, 29.3, 29.2, 29.1, 26.0, 22.7, 14.1.

### Example 2

### Synthesis of Poly[2,3-bis-(3-octyloxyphenyl)quinoxaline-5,8-diyl-alt-thiophene-2,5-diyl]

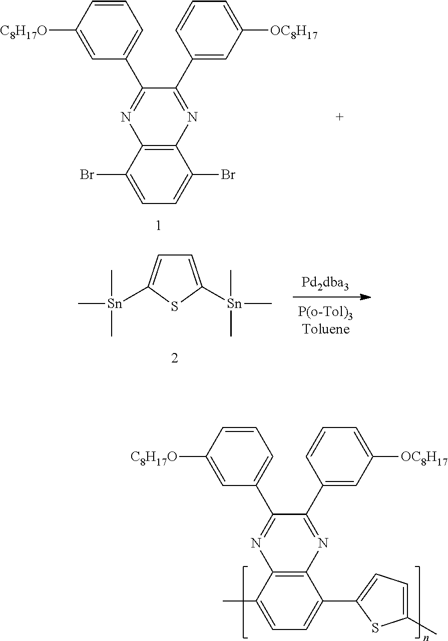

In a 25 mL dry flask, compound 1 (349 mg, 0.5 mmol), 2 (205 mg, 0.5 mmol), tris(dibenzylideneacetone)dipalladium(0) (Pd₂(dba)₃) (6 mg) and tri(o-tolyl)phosphine (P(o-Tol)₃) (10 mg) were dissolved in degassed toluene (6 mL). The mixture was vigorously stirred at 100° C. for 24 h under nitrogen. After cooling down, the solution was poured into acetone. The polymer was collected by filtration through 0.45 μm Teflon filter. And then the polymer was dissolved in 100 mL of ODCB and mixed with a solution of sodium diethyldithiocarbamate trihydrate (5 g) in distilled water (100 mL) The mixture was stirred at 80° C. overnight under nitrogen. The organic phase was separated and washed three times with water. Then it was poured into 400 mL of acetone. The precipitate was collected by thimble and Soxhlet-extracted with ether and chloroform in order. The chloroform fraction was precipitated in acetone. Finally, the polymer was collected by filtration through 0.45 μm Teflon filter and dried under vacuum at 40° C. overnight (237 mg, 76.6%).

### Example 3

### Synthesis of Poly[2,3-bis-(3-octyloxyphenyl)quinoxaline-5,8-diyl-alt-thieno[3,2-b]thiophene-2,5-diyl]

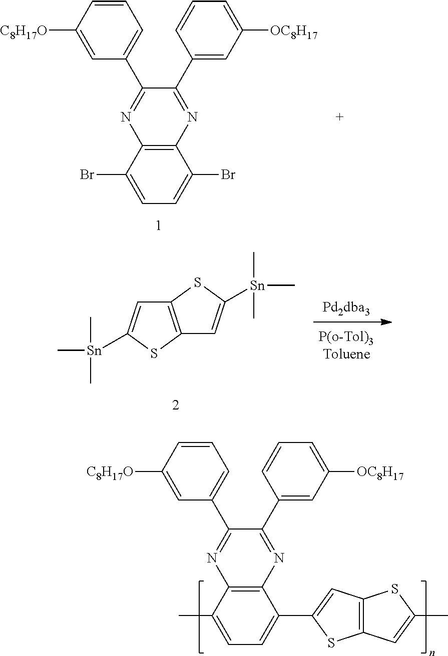

In a 25 mL dry flask, compound 5 (246 mg, 0.3532 mmol), 2 (165 mg, 0.3532 mmol), tris(dibenzylideneacetone)dipalladium(0) (Pd₂(dba)₃) (6.5 mg) and tri(o-tolyl)phosphine (P(o-Tol)₃) (8.6 mg) were dissolved in degassed toluene (17 mL) The mixture was vigorously stirred at 100° C. for 24 h under nitrogen. After cooling down, the solution was poured into acetone. The polymer was collected by filtration through 0.45 μm Teflon filter. And then the polymer was dissolved in 100 mL of ODCB and mixed with a solution of sodium diethyldithiocarbamate trihydrate (5 g) in distilled water (100 mL). The mixture was stirred at 80° C. overnight under nitrogen. The organic phase was separated and washed three times with water. Then it was poured into 400 mL of acetone. The precipitate was collected by thimble and Soxhlet-extracted with ether and chloroform in order. The chloroform fraction was precipitated in acetone. Finally, the polymer was collected by filtration through 0.45 μm Teflon filter and dried under vacuum at 40° C. overnight (130 mg, 44%).

### Example 4

### Synthesis of Poly[2,3-bis-(3-octyloxyphenyl)quinoxaline-5,8-diyl-alt-thieno[2,3-b]thiophene-2,5-diyl]

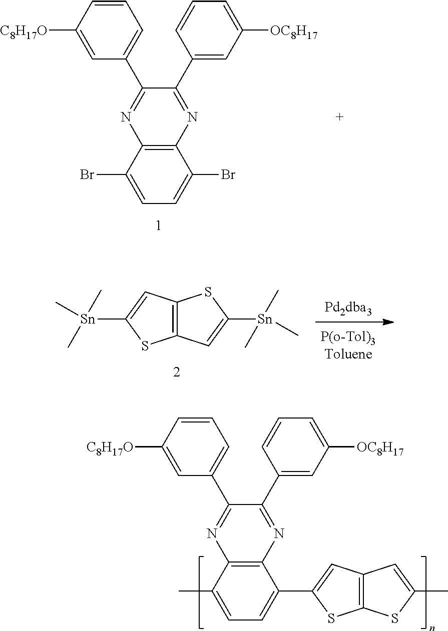

In a 25 mL dry flask, compound 5 (246 mg, 0.3532 mmol), 2 (165 mg, 0.3532 mmol), tris(dibenzylideneacetone)dipalladium(0) (Pd₂(dba)₃) (6.5 mg) and tri(o-tolyl)phosphine (P(o-Tol)₃) (8.6 mg) were dissolved in degassed toluene (17 mL) The mixture was vigorously stirred at 100° C. for 24 h under nitrogen. After cooling down, the solution was poured into acetone. The polymer was collected by filtration through 0.45 μm Teflon filter. And then the polymer was dissolved in 100 mL of ODCB and mixed with a solution of sodium diethyldithiocarbamate trihydrate (5 g) in distilled water (100 mL). The mixture was stirred at 80° C. overnight under nitrogen. The organic phase was separated and washed three times with water. Then it was poured into 400 mL of acetone. The precipitate was collected by thimble and Soxhlet-extracted with ether and chloroform in order. The chloroform fraction was precipitated in acetone. Finally, the polymer was collected by filtration through 0.45 μm Teflon filter and dried under vacuum at 40° C. overnight (200 mg, 67%).

Polymers 1-54 can be evaluated in field effect transistors and in single cell polymer-fullerene BHJ solar cells both in normal and inverted structure. The big advantage of field effect transistors and BHJ cells is their simple processing. All active layers can be processed from solution which includes spin coating, doctor blade, spray coating as well as roll to roll.

### Photovoltaic Device Fabrication

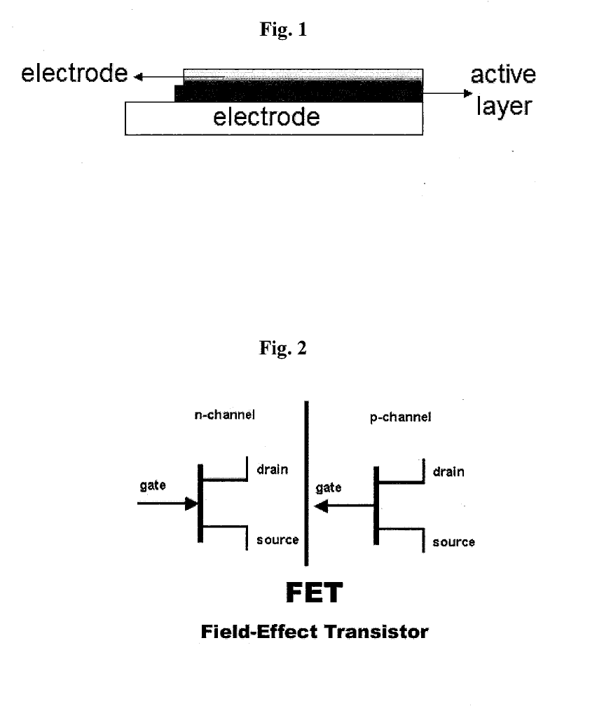

Single layer organic photovoltaic cells are made by sandwiching a layer of organic electronic materials (blend of structures 1-54 with fullerene derivatives such as PC₆₁BM) between two metallic conductors, typically a layer of indium tin oxide (ITO) with high work function and a layer of low work function metal such as silver (Ag), gold (Au) or aluminium (Al). The blends comprising of conjugated polymers of structures 1-54 with fullerene derivatives PC₆₁BM or PC₇₁BM or bis-indene adducts of C₆₀ or C₇₀ or the dihydronaphthyl-based bisadduct of C₆₀ or C₇₀ may be used as active layers in optoelectronic devices having the structure shown in FIG. 1.

Field effect transistors are made by sandwiching a layer of organic electronic materials comprising of structures 1-54 between two metallic conductors, typically a layer of indium tin oxide (ITO) with high work function and a layer of low work function metal such as silver (Ag), gold (Au) or aluminium (Al). The conjugated polymers of structures 1-54 may be used in field effect transistors having the structure shown in FIG. 2.

What is claimed is:

1. A conjugated polymer selected from the group consisting of: 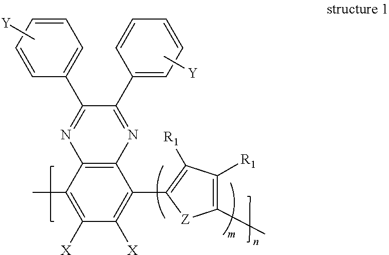
wherein X, Y, Z can be the same or different and is selected from the group consisting of: X=hydrogen or fluorine atoms;
Y=alkyl, alkoxy; in ortho, meta or para positions and can be linear or branch;
Z=oxygen, sulfur, selenium;
m and n can be the same or different and are numbers between 1 to 1000
and R₁: —CₚH₂ₚ₊₁, p≧0; linear or branch. 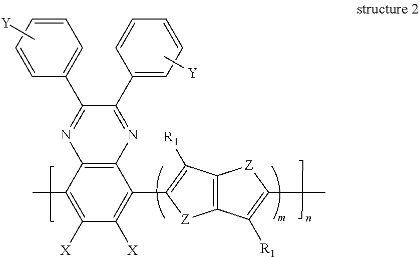
wherein X, Y, Z can be the same or different and is selected from the group consisting of: X=hydrogen or fluorine atoms;
Y=alkyl, alkoxy; in ortho, meta or para positions and can be linear or branch;
Z=oxygen, sulfur, selenium;
m and n can be the same or different and are numbers between 1 to 1000
and R₁: —CₚH₂ₚ₊₁, p≧0; linear or branch. 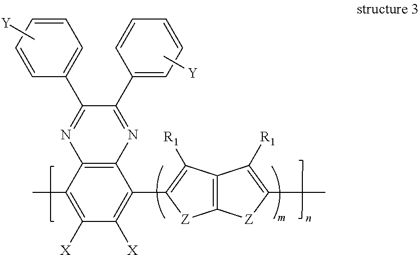
wherein X, Y, Z can be the same or different and is selected from the group consisting of: X=hydrogen or fluorine atoms;
Y=alkyl, alkoxy; in ortho, meta or para positions and can be linear or branch;
Z=oxygen, sulfur, selenium;
m and n can be the same or different and are numbers between 1 to 1000
and R₁: —CₚH₂ₚ₊₁, p≧0; linear or branch. 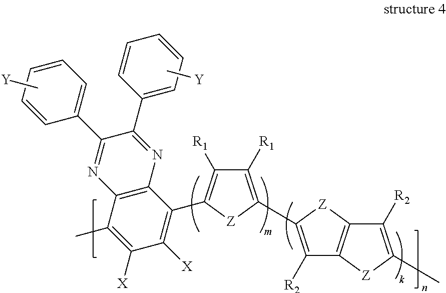
wherein X, Y, Z can be the same or different and is selected from the group consisting of: X=hydrogen or fluorine atoms;
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}H_{2w+1}, w≧0; linear or branch. 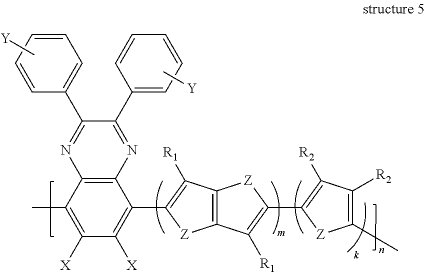
wherein X, Y, Z can be the same or different and is selected from the group consisting of: X=hydrogen or fluorine atoms;
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}H_{2w+1}, w≧0; linear or branch. 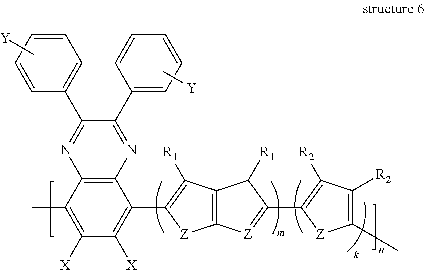
wherein X, Y, Z can be the same or different and is selected from the group consisting of: X=hydrogen or fluorine atoms;
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}H_{2w+1}, w≧0; linear or branch. 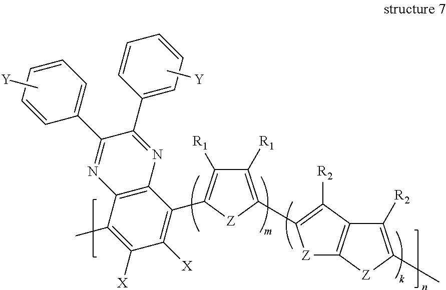
wherein X, Y, Z can be the same or different and is selected from the group consisting of: X=hydrogen or fluorine atoms;
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}H_{2w+1}, w≧0; linear or branch. 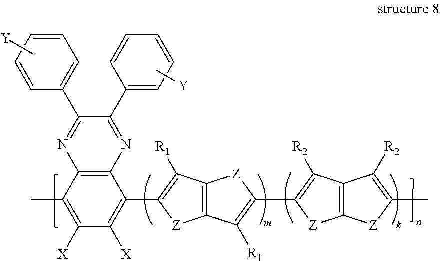
wherein X, Y, Z can be the same or different and is selected from the group consisting of: X=hydrogen or fluorine atoms;
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}H_{2w+1}, w≧0; linear or branch. 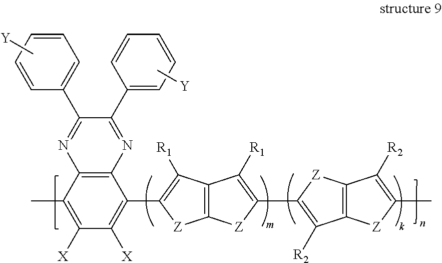
wherein X, Y, Z can be the same or different and is selected from the group consisting of: X=hydrogen or fluorine atoms;
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}H_{2w+1}, w≧0; linear or branch. 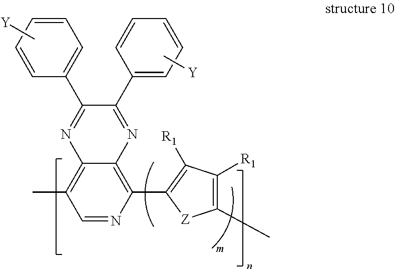
wherein Y, Z can be the same or different and is selected from the group consisting of:
Y=alkyl, alkoxy; in ortho, meta or para positions and can be linear or branch;
Z=oxygen, sulfur, selenium;
m and n can be the same or different and are numbers between 1 to 1000
and R₁: —CₚH₂ₚ₊₁, p≧0; linear or branch. 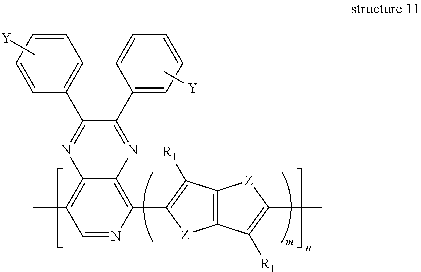
wherein Y, Z can be the same or different and is selected from the group consisting of:
Y=alkyl, alkoxy; in ortho, meta or para positions and can be linear or branch;
Z=oxygen, sulfur, selenium;
m and n can be the same or different and are numbers between 1 to 1000
and R₁: —CₚH₂ₚ₊₁, p≧0; linear or branch. 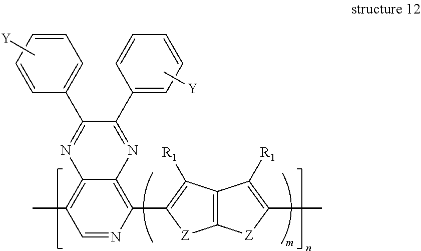
wherein Y, Z can be the same or different and is selected from the group consisting of:
Y=alkyl, alkoxy; in ortho, meta or para positions and can be linear or branch;
Z=oxygen, sulfur, selenium;
m and n can be the same or different and are numbers between 1 to 1000
and R₁: —CₚH₂ₚ₊₁, p≧0; linear or branch. 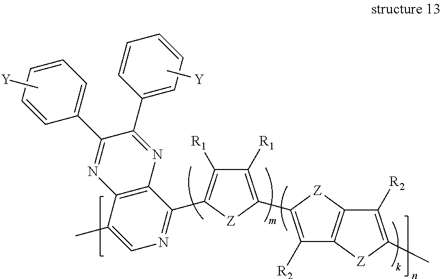
wherein Y, Z can be the same or different and is selected from the group consisting of:
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}/H_{2w+1}, w≧0; linear or branch. 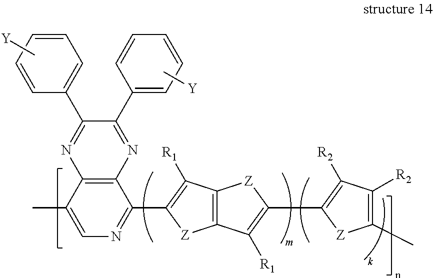
wherein Y, Z can be the same or different and is selected from the group consisting of:
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}H₂₊₁, w≧0; linear or branch. 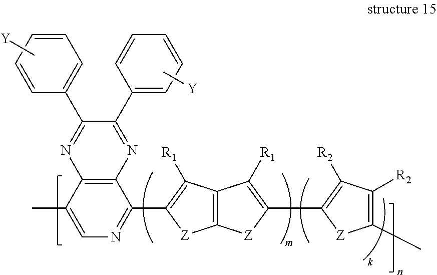
wherein Y, Z can be the same or different and is selected from the group consisting of:
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}H_{2w+1}, w≧0; linear or branch. 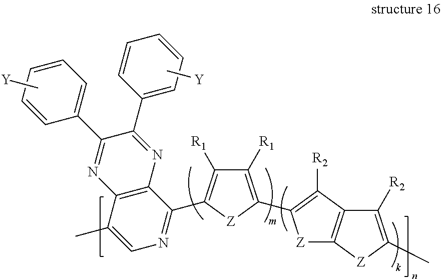
wherein Y, Z can be the same or different and is selected from the group consisting of:
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}H_{2w+1}, w≧0; linear or branch. 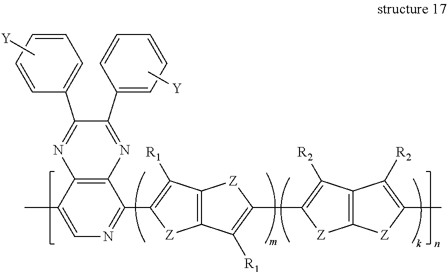
wherein Y, Z can be the same or different and is selected from the group consisting of:
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}H_{2w+1}, w≧0; linear or branch. 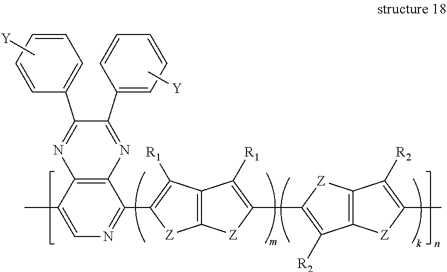
wherein Y, Z can be the same or different and is selected from the group consisting of:
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}H_{2w+1}, w≧0; linear or branch.

2. A conjugated polymer selected from the group consisting of: 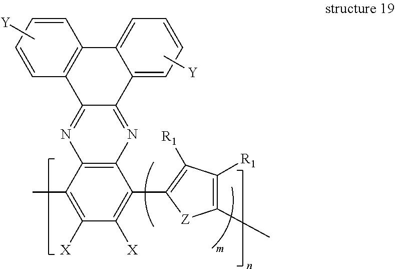
wherein X, Y, Z can be the same or different and is selected from the group consisting of: X=hydrogen or fluorine atoms;
Y=alkyl, alkoxy; in ortho, meta or para positions and can be linear or branch;
Z=oxygen, sulfur, selenium;
m and n can be the same or different and are numbers between 1 to 1000
and R₁: —CₚH₂ₚ₊₁, p≧0; linear or branch. 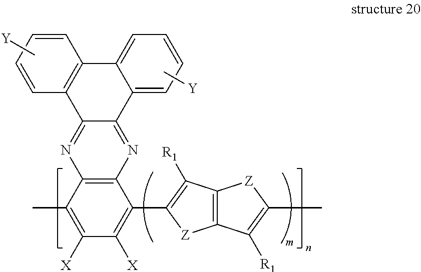
wherein X, Y, Z can be the same or different and is selected from the group consisting of: X=hydrogen or fluorine atoms;
Y=alkyl, alkoxy; in ortho, meta or para positions and can be linear or branch;
Z=oxygen, sulfur, selenium;
m and n can be the same or different and are numbers between 1 to 1000
and R₁: —CₚH₂ₚ₊₁, p≧0; linear or branch. 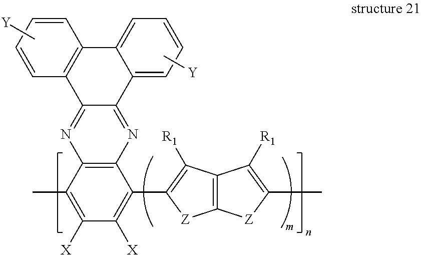
wherein X, Y, Z can be the same or different and is selected from the group consisting of: X=hydrogen or fluorine atoms;
Y=alkyl, alkoxy; in ortho, meta or para positions and can be linear or branch;
Z=oxygen, sulfur, selenium;
m and n can be the same or different and are numbers between 1 to 1000
and R₁: —CₚH₂ₚ₊₁, p≧0; linear or branch. 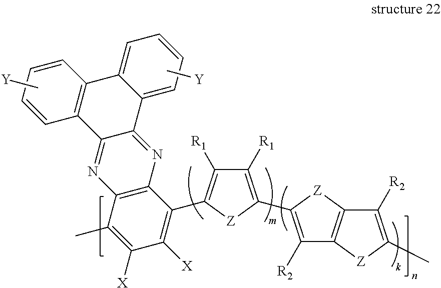
wherein X, Y, Z can be the same or different and is selected from the group consisting of: X=hydrogen or fluorine atoms;
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}H_{2w+1}, w≧0; linear or branch. 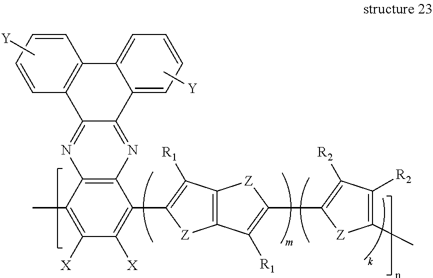
wherein X, Y, Z can be the same or different and is selected from the group consisting of: X=hydrogen or fluorine atoms;
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}H_{2w+1}, w≧0; linear or branch. 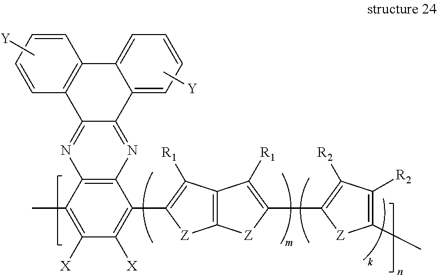
wherein X, Y, Z can be the same or different and is selected from the group consisting of: X=hydrogen or fluorine atoms;
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}H_{2w+1}, w≧0; linear or branch. 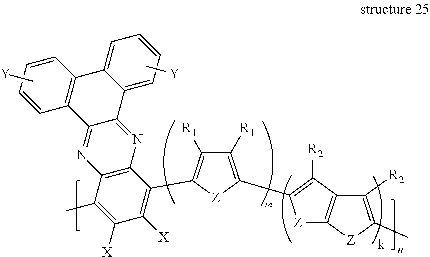
wherein X, Y, Z can be the same or different and is selected from the group consisting of: X=hydrogen or fluorine atoms;
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}H_{2w+1}, w≧0; linear or branch. 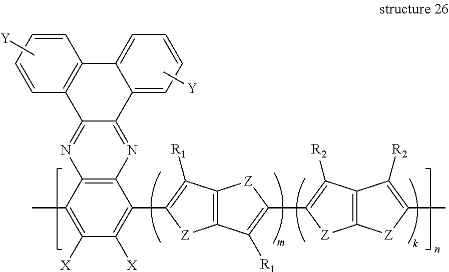
wherein X, Y, Z can be the same or different and is selected from the group consisting of: X=hydrogen or fluorine atoms;
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}H_{2w+1}, w≧0; linear or branch. 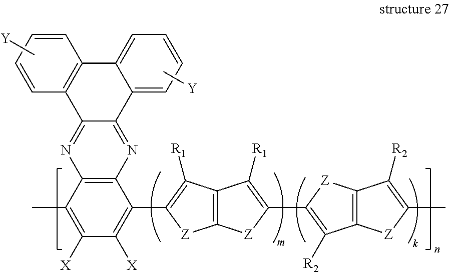
wherein X, Y, Z can be the same or different and is selected from the group consisting of: X=hydrogen or fluorine atoms;
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}H_{2w+1}, w≧0; linear or branch. 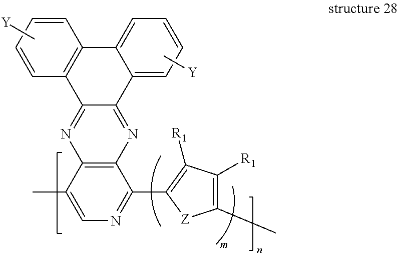
wherein Y, Z can be the same or different and is selected from the group consisting of:
Y=alkyl, alkoxy; in ortho, meta or para positions and can be linear or branch;
Z=oxygen, sulfur, selenium;
m and n can be the same or different and are numbers between 1 to 1000 and R₁: —CₚH₂ₚ₊₁, p≧0; linear or branch. 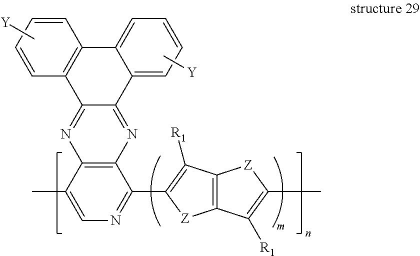
wherein Y, Z can be the same or different and is selected from the group consisting of:
Y=alkyl, alkoxy; in ortho, meta or para positions and can be linear or branch;
Z=oxygen, sulfur, selenium;
m and n can be the same or different and are numbers between 1 to 1000
and R₁: —CₚH₂ₚ₊₁, p≧0; linear or branch. 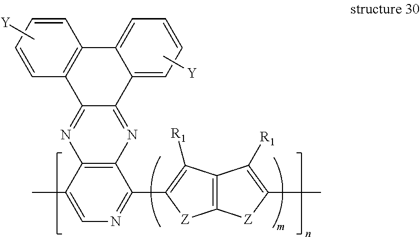
wherein Y, Z can be the same or different and is selected from the group consisting of:
Y=alkyl, alkoxy; in ortho, meta or para positions and can be linear or branch;
Z=oxygen, sulfur, selenium;
m and n can be the same or different and are numbers between 1 to 1000
and R₁: —CₚH₂ₚ₊₁, p≧0; linear or branch. 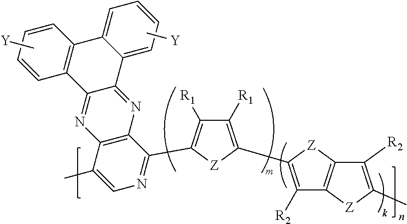
wherein Y, Z can be the same or different and is selected from the group consisting of:
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}H_{2w+1}, w≧0; linear or branch. 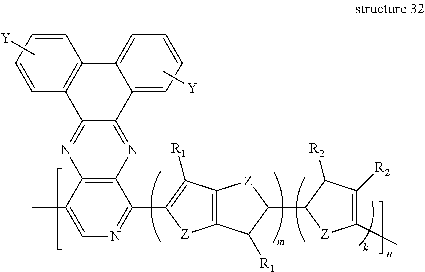
wherein Y, Z can be the same or different and is selected from the group consisting of:
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}H_{2w+1}, w≧0; linear or branch. 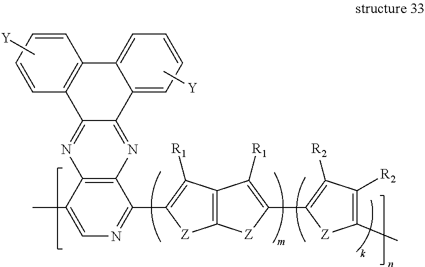
wherein Y, Z can be the same or different and is selected from the group consisting of:
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}H_{2w+1}, w≧0; linear or branch. 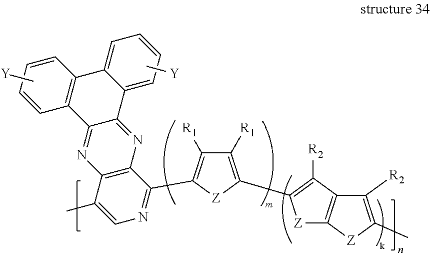
wherein Y, Z can be the same or different and is selected from the group consisting of:
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}H_{2w+1}, w≧0; linear or branch. 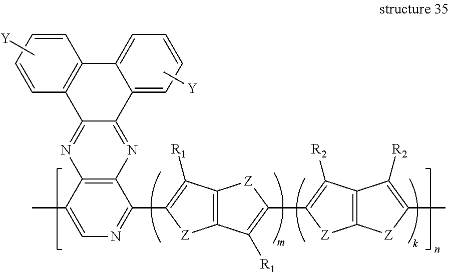
wherein Y, Z can be the same or different and is selected from the group consisting of:
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}H_{2w+1}, w≧0; linear or branch. 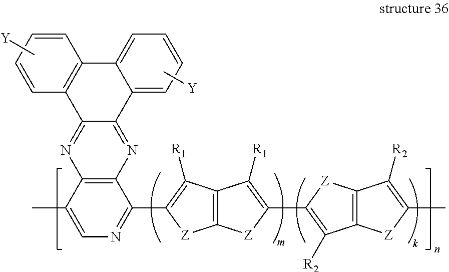
wherein Y, Z can be the same or different and is selected from the group consisting of:
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}H_{2w+1}, w≧0; linear or branch.

3. A conjugated polymer selected from the group consisting of: 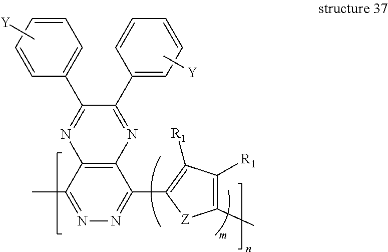
wherein Y, Z can be the same or different and is selected from the group consisting of:
Y=alkyl, alkoxy; in ortho, meta or para positions and can be linear or branch;
Z=oxygen, sulfur, selenium;
m and n can be the same or different and are numbers between 1 to 1000
and R₁: —CₚH₂ₚ₊₁, p≧0; linear or branch. 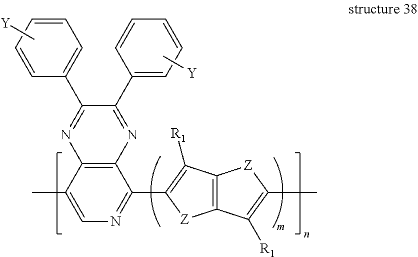
wherein Y, Z can be the same or different and is selected from the group consisting of:
Y=alkyl, alkoxy; in ortho, meta or para positions and can be linear or branch;
Z=oxygen, sulfur, selenium;
m and n can be the same or different and are numbers between 1 to 1000
and R₁: —CₚH₂ₚ₊₁, p≧0; linear or branch. 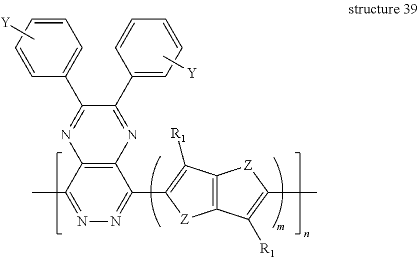
wherein Y, Z can be the same or different and is selected from the group consisting of:
Y=alkyl, alkoxy; in ortho, meta or para positions and can be linear or branch;
Z=oxygen, sulfur, selenium;
m and n can be the same or different and are numbers between 1 to 1000
and R₁: —CₚH₂ₚ₊₁, p≧0; linear or branch. 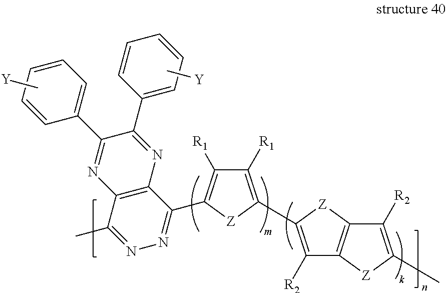
wherein Y, Z can be the same or different and is selected from the group consisting of:
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}H_{2w+1}, w≧0; linear or branch. 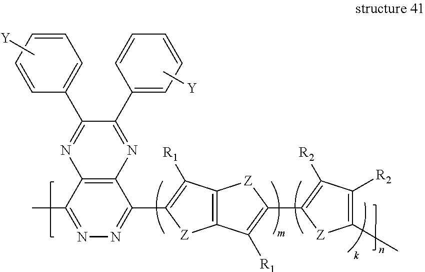
wherein Y, Z can be the same or different and is selected from the group consisting of:
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}H_{2w+1}, w≧0; linear or branch. 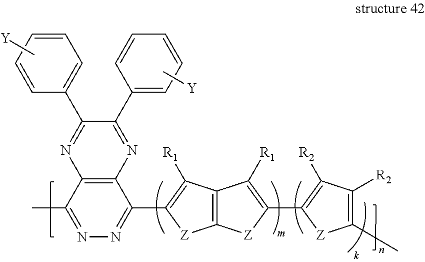
wherein Y, Z can be the same or different and is selected from the group consisting of:
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}H_{2w+1}, w≧0; linear or branch. 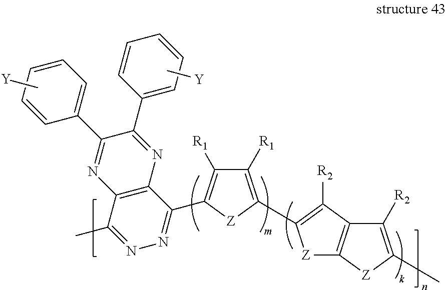
wherein Y, Z can be the same or different and is selected from the group consisting of:
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}H_{2w+1}, w≧0; linear or branch. 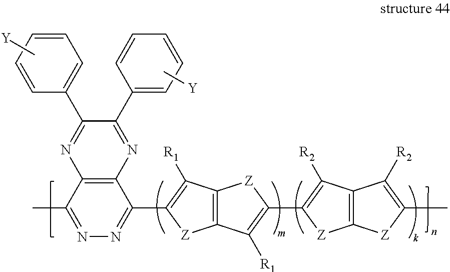
wherein Y, Z can be the same or different and is selected from the group consisting of:
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}H_{2w+1}, w≧0; linear or branch. 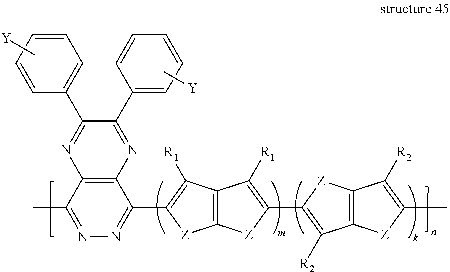
wherein Y, Z can be the same or different and is selected from the group consisting of:
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}H_{2w+1}, w≧0; linear or branch. 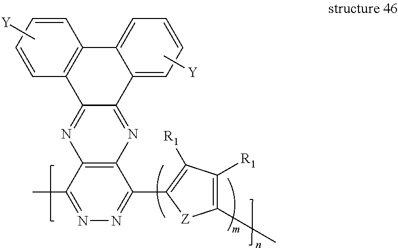
wherein Y, Z can be the same or different and is selected from the group consisting of:
Y=alkyl, alkoxy; in ortho, meta or para positions and can be linear or branch;
Z=oxygen, sulfur, selenium;
m and n can be the same or different and are numbers between 1 to 1000
and R₁: —CₚH₂ₚ₊₁, p≧0; linear or branch. 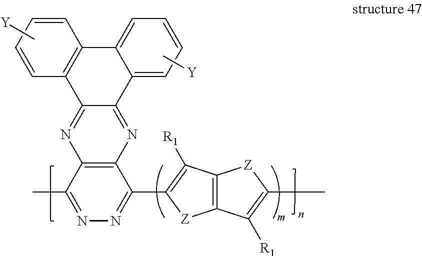
wherein Y, Z can be the same or different and is selected from the group consisting of:
Y=alkyl, alkoxy; in ortho, meta or para positions and can be linear or branch;
Z=oxygen, sulfur, selenium;
m and n can be the same or different and are numbers between 1 to 1000
and R₁: —CₚH₂ₚ₊₁, p≧0; linear or branch. 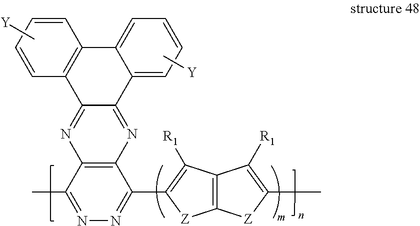
wherein Y, Z can be the same or different and is selected from the group consisting of:
Y=alkyl, alkoxy; in ortho, meta or para positions and can be linear or branch;
Z=oxygen, sulfur, selenium;
m and n can be the same or different and are numbers between 1 to 1000
and R₁: —CₚH₂ₚ₊₁, p≧0; linear or branch. 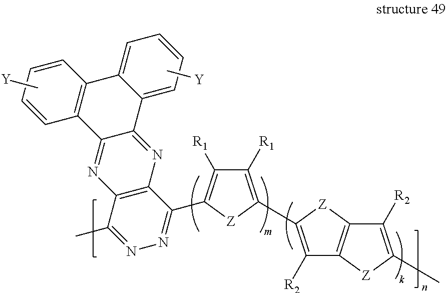
wherein Y, Z can be the same or different and is selected from the group consisting of:
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}H_{2w+1}, w≧0; linear or branch. 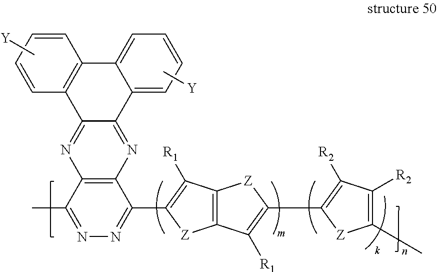
wherein Y, Z can be the same or different and is selected from the group consisting of:
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}H_{2w+1}, w≧0; linear or branch. 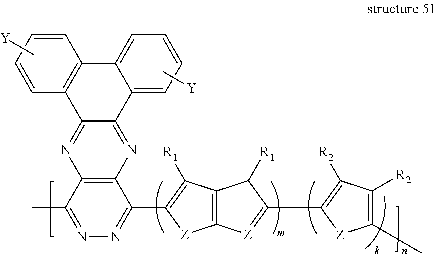
wherein Y, Z can be the same or different and is selected from the group consisting of:
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}H_{2w+1}, w≧0; linear or branch. 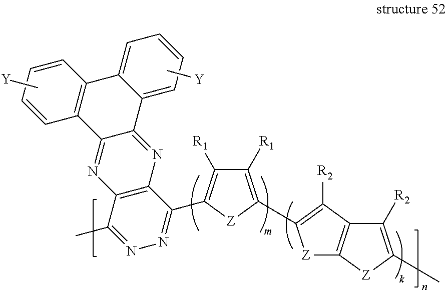
wherein Y, Z can be the same or different and is selected from the group consisting of:
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}H_{2w+1}, w≧0; linear or branch. 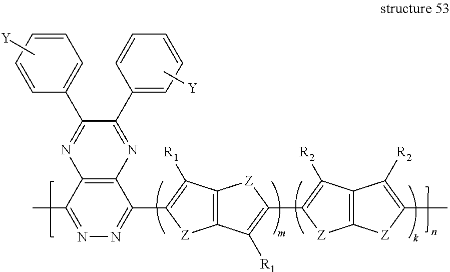
wherein Y, Z can be the same or different and is selected from the group consisting of:
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}H_{2w+1}, w≧0; linear or branch. 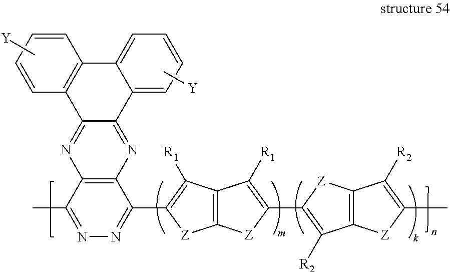
wherein Y, Z can be the same or different and is selected from the group consisting of:
Y=alkyl, alkoxy; in ortho, meta or para positions and can be linear or branch;
Z=oxygen, sulfur, selenium;
m, k and n can be the same or different and are numbers between 1 to 1000
and R₁: —CₚH₂ₚ₊₁, p≧0; linear or branch
and R₂: —C_{w}H_{2w+1}, w≧0; linear or branch.

4. A process for preparing the conjugated polymers of claim 1, wherein the process comprises Suzuki or Stille cross coupling, wherein the organic palladium catalyst is Pd₂(dba)₃/P(o-Tol)₃, Pd(PPh₃)₄ or Pd(PPh₃)₂Cl₂ under conditions such that the polymer structures 1-54 are formed.

5. A process for preparing the conjugated polymers of claim 2, wherein the process comprises Suzuki or Stille cross coupling, wherein the organic palladium catalyst is Pd₂(dba)₃/P(o-Tol)₃, Pd(PPh₃)₄ or Pd(PPh₃)₂Cl₂ under conditions such that the polymer structures 1-54 are formed.

6. A process for preparing the conjugated polymers of claims 3, wherein the process comprises Suzuki or Stille cross coupling, wherein the organic palladium catalyst is Pd₂(dba)₃/P(o-Tol)₃, Pd(PPh₃)₄ or Pd(PPh₃)₂Cl₂ under conditions such that the polymer structures 1-54 are formed.

7. A method of preparing a thin layer of the conjugated polymers of claim 1, the method comprising:
(a) depositing a layer of a polymer structure of claim 1 by calendaring, screen printing, drop casting, dr blade, spin coating or spraying;
(b) drying the layer deposited in step (a)
(c) depositing a layer of a blend comprising the polymer structure of claims 1 with a fullerene (C₆₀, C₇₀, C₈₄) derivative by calendaring, screen printing, drop casting, doctor blade, spin coating or spraying; and
(d) drying the layer deposited in step (c).

8. A method of preparing a thin layer of the conjugated polymers of claim 2, the method comprising:
(a) depositing a layer of a polymer structure of claim 2 by calendaring, screen printing, drop casting, dr blade, spin coating or spraying;
(b) drying the layer deposited in step (a)
(c) depositing a layer of a blend comprising the polymer structure of claim 2 with a fullerene (C₆₀, C₇₀, C₈₄) derivative by calendaring, screen printing, drop casting, doctor blade, spin coating or spraying; and
(d) drying the layer deposited in step (c).

9. A method of preparing a thin layer of the conjugated polymers of claim 3, the method comprising:
(a) depositing a layer of a polymer structure of claim 3 by calendaring, screen printing, drop casting, dr blade, spin coating or spraying;
(b) drying the layer deposited in step (a)
(c) depositing a layer of a blend comprising the polymer structure of claim 3 with a fullerene (C₆₀, C₇₀, C₈₄) derivative by calendaring, screen printing, drop casting, doctor blade, spin coating or spraying; and
(d) drying the layer deposited in step (c).

10. An optoelectronic device comprising one or more of the thin layer of claim 7 as active layer components.

11. An optoelectronic device comprising one or more of the thin layer of claim 8 as active layer components.

12. An optoelectronic device comprising one or more of the thin layer of claim 9 as active layer components.
